(19) United States
(12) Patent Application Publication
(10) Pub. No.: US 2026/0211163 A1
(43) Pub. Date: Jul. 23, 2026

(54) DISPLAY DEVICE AND ELECTRONIC DEVICE INCLUDING THE SAME

(71) Applicant: Samsung Display Co., LTD., Yongin-si (KR)

(72) Inventors: Hee Young LEE, Yongin-si (KR); Sung-Guk AN, Yongin-si (KR); Jisun KO, Yongin-si (KR); Jungwook Kim, Yongin-si (KR); Jimi Eom, Yongin-si (KR); jooho Yun, Yongin-si (KR); Seungri Lee, Yongin-si (KR); Chul Ho JEONG, Yongin-si (KR); So Yeon HAN, Yongin-si (KR)

(21) Appl. No.: 19/332,745

(22) Filed: Sep. 18, 2025

(30) Foreign Application Priority Data
Jan. 20, 2025 (KR) 10-2025-0008348

(51) Int. Cl. G02B 5/00; G02B 1/11; G02B 1/14; G06F 1/16

(52) U.S. Cl. CPC G02B 5/003; G02B 1/11; G02B 1/14; G06F 1/1641; G06F 1/1656

(57) ABSTRACT

A display device includes: a display panel, a window disposed on a front surface of the display panel, a base layer disposed on the window, a coating layer disposed on the base layer, and an adhesive layer disposed between the window and the base layer, where at least one of the base layer, the coating layer, and the adhesive layer includes an ultraviolet absorbent, and where a content of the ultraviolet absorbent is about 1 wt % to about 10 wt %.

This application claims priority to Korean Patent Application No. 10-2025-0008348, filed on Jan. 20, 2025, and all the benefits accruing therefrom under 35 U.S.C. § 119, the content of which in its entirety is herein incorporated by reference.

### BACKGROUND

### 1. Field

The disclosure relates to a display device and an electronic device including the same, and more particularly, to a display device and an electronic device including the same with improved color characteristics.

### 2. Description of the Related Art

Display devices are devices for displaying screens, including liquid crystal displays (“LCDs”), organic light-emitting diode (“OLED”) devices, or the like. Such display devices are used in various electronic devices such as mobile phones, navigation devices, digital cameras, electronic books, portable game consoles, or various terminals.

### SUMMARY

Embodiments attempt to provide a display device and an electronic device including the same with uniform reflection color.

In an embodiment of the disclosure, a display device includes: a display panel, a window disposed on a front surface of the display panel, an optical film disposed on the window, and an adhesive layer disposed between the window and the optical film, where the optical film includes a base layer disposed on the window and a coating layer disposed on the base layer, where at least one of the base layer, the coating layer, and the adhesive layer includes an ultraviolet absorbent, and where a content of the ultraviolet absorbent may be about 1 wt % to about 10 wt %.

In an embodiment, the content of the ultraviolet absorbent may be about 1 wt % to about 5 wt %.

In an embodiment, the content of the ultraviolet absorbent may be about 1 wt % to about 3 wt %.

In an embodiment, the coating layer may include a first coating layer and a second coating layer, and the second coating layer may include the ultraviolet absorbent.

In an embodiment, a thickness of the second coating layer may be about 10 micrometers (μm) or less.

In an embodiment, the second coating layer may be disposed between the first coating layer and the base layer.

In an embodiment, the first coating layer may be disposed between the second coating layer and the base layer.

In an embodiment, the base layer may include a first base layer and a second base layer, and the second base layer may include the ultraviolet absorbent.

In an embodiment, the adhesive layer may include a first adhesive layer and a second adhesive layer, and the second adhesive layer may include the ultraviolet absorbent.

In an embodiment, each of the base layer and the coating layer includes the ultraviolet absorbent, and the thickness of the base layer may be greater than the thickness of the coating layer, and the content of the ultraviolet absorbent in the base layer may be greater than the content of the ultraviolet absorbent in the coating layer.

In an embodiment, each of the adhesive layer and the coating layer includes the ultraviolet absorbent, and the thickness of the adhesive layer may be greater than the thickness of the coating layer, and the content of the ultraviolet absorbent in the adhesive layer may be greater than the content of the ultraviolet absorbent in the coating layer.

In an embodiment, the optical film may further include a low refractive layer disposed on the coating layer and having a refractive index.

In an embodiment, the refractive index of the low refractive layer may be about 1.48 or less.

In an embodiment, the optical film may further include a high refractive layer disposed between the coating layer and the low refractive layer and having a refractive index higher than the refractive index of the low refractive layer.

In an embodiment, the refractive index of the high refractive layer may be about 1.55 or more.

In an embodiment, the optical film may further include an anti-reflection layer disposed at an outermost.

In an embodiment, the hardness of the optical film may be about 30 Vickers hardness (Hv) or more.

In an embodiment, the crack strain of the optical film may be about 2% or more.

In an embodiment, the display panel may include a color filter layer.

In an embodiment, a display device may transmit about 10% or less of light having a wavelength of 405 nanometers (nm) or less, and about 85% or more of light having a wavelength of 450 nm or more.

In an embodiment of the disclosure, an electronic device includes a display device, where the display device includes: a display panel, a window disposed on a front surface of the display panel, an optical film disposed on the window, and an adhesive layer disposed between the window and the optical film, where the optical film includes a base layer disposed on the window and a coating layer disposed on the base layer, where at least one of the base layer, the coating layer, and the adhesive layer includes an ultraviolet absorbent, and where a content of the ultraviolet absorbent may be about 1 wt % to about 10 wt %.

In an embodiment, the display device may transmit about 10% or less of light having a wavelength of 405 nm or less, and about 85% or more of light having a wavelength of 450 nm or more.

In an embodiment, the content of the ultraviolet absorbent may be about 1 wt % to 3 wt %.

By the embodiments, a display device and an electronic device including the same may be provided, where bluish reflection color phenomenon is improved and display quality is enhanced by reducing external light reflectance.

### BRIEF DESCRIPTION OF THE DRAWINGS

The above and other embodiments, advantages and features of this disclosure will become more apparent by describing in further detail embodiments thereof with reference to the accompanying drawings.

FIG. 1 is a perspective view of an embodiment of a display device.

FIG. 2 is a perspective view of an embodiment of a display device.

FIG. 3 is an exploded perspective view of an embodiment of a display device.

FIGS. 4 and 5 are cross-sectional views of an embodiment of a display area of a display device.

FIGS. 6 to 12 are cross-sectional views of an embodiment of a portion of a display device.

FIG. 13 is a graph showing an embodiment of transmittance of light according to wavelength and intensity of light according to wavelength of a light-emitting layer emitting blue light of a display device.

FIG. 14 is a block diagram of an embodiment of an electronic device.

FIG. 15 are schematic diagrams of embodiments of electronic devices.

### DETAILED DESCRIPTION

Hereinafter, various embodiments will be described in detail with reference to the accompanying drawings to enable one skilled in the art to easily implement them. The disclosure may be implemented in various different forms and is not limited to the embodiments described herein.

For clarity of the disclosure, portions unrelated to the description have been omitted, and throughout the specification, like reference numerals have been used for like components.

Also, the size and thickness of each component shown in the drawings are arbitrarily shown for convenience of description, and thus the disclosure is not necessarily limited to what is shown. The thicknesses are exaggerated in the drawings to clearly express various layers and regions. And in the drawings, for convenience of description, the thicknesses of some layers and regions are exaggerated.

Also, when any part such as a layer, film, region, or plate is described to be disposed “on” or “above” another part, it includes both cases where it is disposed “directly on” the other part and where another part is in between. Conversely, when any part is described to be disposed “directly on” another part, it means that no other part is in between. Also, when any part is described to be disposed “on” or “above” a reference part, it means that it is disposed above or below the reference part and does not necessarily mean that it is disposed “on” or “above” in the direction opposite to gravity.

Also, throughout the specification, when any part is described to “include” a component, unless specifically stated otherwise, it does not exclude other components but may include other components.

Also, throughout the specification, “in a plan view” means when the target portion is viewed from above, and “in cross-sectional view” means when a vertical cross-section of the target portion is viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

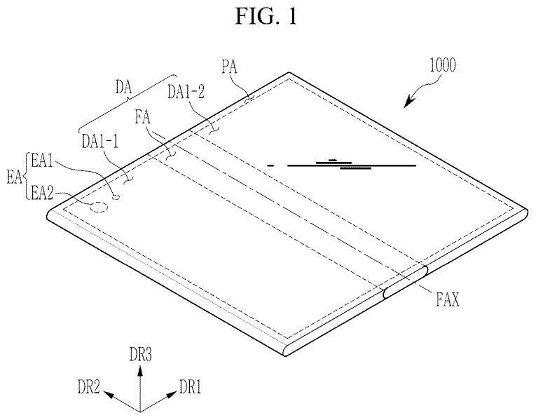

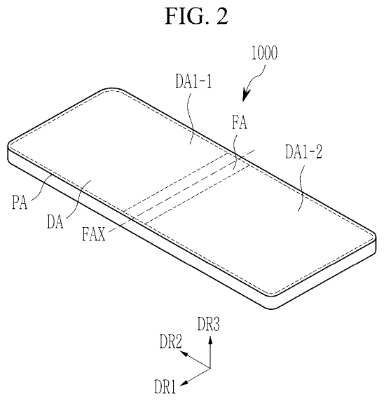

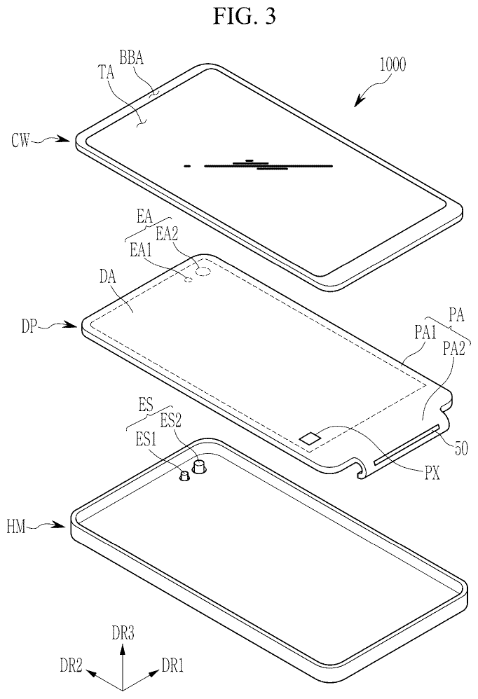

Hereinafter, a display device in an embodiment will be described with reference to FIGS. 1 to 3. FIG. 1 is a perspective view of an embodiment of a display device, FIG. 2 is a perspective view of an embodiment of a display device, and FIG. 3 is an exploded perspective view of an embodiment of a display device.

First, referring to FIG. 1, a display device 1000 in an embodiment is a device for displaying moving images or still images and may be used as a display screen for various products such as portable electronic devices including mobile phones, smart phones, tablet personal computers (“PCs”), mobile communication terminals, electronic notebooks, electronic books, portable multimedia players (“PMPs”), navigation devices, Ultra Mobile PCs (“UMPCs”), as well as televisions, notebooks, monitors, advertisement boards, and internet of things (“IOT”). Also, the display device 1000 in an embodiment may be used in wearable devices such as smart watches, watch phones, glasses-type displays, and head disposed (e.g., mounted) displays (“HMD”). Also, the display device 1000 in an embodiment may be used as an instrument panel of a vehicle, a Center Information Display (“CID”) disposed in a center fascia or dashboard of a vehicle, a room mirror display replacing a vehicle's side mirror, or a display disposed on the back of front seats for back seat entertainment in a vehicle. FIG. 1 shows, for convenience of description, the display device 1000 being used as a smart phone.

The display device 1000 may display images on a display surface parallel to first direction DR1 and second direction DR2 toward third direction DR3. The display surface may correspond to a front surface of the display device 1000. The images may include both dynamic and still images.

In this embodiment, the front surface (or upper surface) and rear surface (or lower surface) of each component are defined based on the direction in which images are displayed. The front and rear surfaces oppose each other in the third direction DR3, and the normal direction of each front and rear surface may be parallel to the third direction DR3. The separation distance between the front and rear surfaces in the third direction DR3 may correspond to the thickness of the display panel in the third direction DR3.

In an embodiment, the display device 1000 may be a foldable device. In this specification, a foldable device refers to a device capable of folding, including not only devices that are folded but also devices that may have both folded and unfolded states. Also, folding typically includes bending at an angle of about 180°, but is not limited thereto and may include cases where the bending angle exceeds or falls short of 180°, e.g., bending at an angle of 90° or more but less than 180°, or 120° or more but less than 180°. Furthermore, even when complete folding is not achieved, a state that deviates from the unfolded state and is bent may be also referred to as a folded state. In an embodiment, even when bent at an angle of 90° or less, as long as the maximum folding angle may reach 90° or more, it may be expressed as being in a folded state to distinguish it from an unfolded state, for example. The radius of curvature during folding may be 5 millimeters (mm) or less, and for example, may be in the range of about 1 mm to about 2 mm, or about 1.5 mm, but is not limited thereto.

In an embodiment, the display device 1000 may include a display area DA, a component area EA, and a non-display area PA.

The display area DA (also referred to as the main display area) and the component area EA include multiple light-emitting diodes and multiple pixel circuit portions that generate and deliver emission current to each of the light-emitting diodes. Here, one pixel refers to one light-emitting diode and one pixel circuit portion. In the display area DA and component area EA, one pixel circuit portion and one light-emitting diode may be formed in a one-to-one correspondence.

The display area DA may include a first display area DA1-1, a second display area DA1-2, and a folding area FA. The first display area DA1-1 and second display area DA1-2 may be disposed on the left and right sides based on (or centered on) a folding axis FAX, respectively, and the folding area FA may be disposed between the first display area DA1-1 and second display area DA1-2. At this time, when folded outward based on the folding axis FAX, the first display area DA1-1 and second display area DA1-2 are disposed on opposite sides in the third direction DR3 and may display images in both directions. Also, when folded inward based on the folding axis FAX, the first display area DA1-1 and second display area DA1-2 may not be visible from the outside.

In an embodiment, the folding axis FAX may extend along the second direction DR2 and may cross the display area DA.

FIG. 1 shows one folding area FA, but the display device 1000 in an embodiment may include one or more folding areas FA. The one or more folding areas FA may be folded around different axes, e.g., axes parallel to the first direction DR1 and/or the second direction DR2, and the position and width of the folding area FA in the display device 1000 may be variously changed.

The non-display area PA is next (adjacent) to the display area DA and may surround the display area DA. The non-display area PA does not display images and may have driving circuits or driving wirings arranged therein.

The component area EA may include a first component area EA1 and a second component area EA2. The first component area EA1 and second component area EA2 may be at least partially surrounded by the display area DA. The first component area EA1 and second component area EA2 are shown as being spaced apart from each other, but are not limited thereto and may be at least partially connected. The first component area EA1 and second component area EA2 may be areas where optical elements ES using infrared light, visible light, or sound (refer to ES in FIG. 3; also referred to as components) are arranged underneath.

Referring to FIG. 2, a display device 1000 in an embodiment may have a length in the second direction DR2 greater than a length in the first direction DR1. When viewed by a user, it may be in a quadrangular shape, e.g., rectangular shape that is longer in the vertical direction.

The display device 1000 in an embodiment may include a folding axis FAX extending in the first direction DR1. The display device 1000 may be folded based on the folding axis FAX, and when folded, the length in the second direction DR2 may be reduced by half.

Next, referring to FIG. 3, the overall structure of the display device 1000 will be described. The display device 1000 in FIG. 3 is shown as flat, but it may also be applied to a foldable display device as in the embodiments of FIGS. 1 and 2.

The display device 1000 may include a cover window CW, a housing HM, a display panel DP, and an optical element ES. In an embodiment, the cover window CW and housing HM may be combined to form the exterior appearance of the display device 1000.

The cover window CW may include an insulating panel. In an embodiment, the cover window CW may include glass, plastic, or any combinations thereof, for example.

The front surface of the cover window CW may define the front surface of the display device 1000. The transmission area TA may be an optically transparent area. In an embodiment, the transmission area TA may be an area having a visible light transmittance of about 90% or more, for example.

The blocking area BBA may define the shape of the transmission area TA. The blocking area BBA is next (adjacent) to the transmission area TA and may surround the transmission area TA. The blocking area BBA may have relatively lower light transmittance compared to the transmission area TA. The blocking area BBA may include light-blocking opaque material. The blocking area BBA may have a predetermined color. The blocking area BBA may be defined by a bezel layer provided separately from the transparent substrate defining the transmission area TA, or may be defined by an ink layer inserted or colored in the transparent substrate.

The display panel DP may include display pixels PX and a driving portion 50, with the display pixels PX being disposed within the display area DA and component area EA. The display panel DP may include a front surface including the display area DA and non-display area PA. In an embodiment, the display area DA and component area EA are areas where display pixels (also referred to as pixels) PX are included to display images, and simultaneously are areas where touch sensors are disposed above the pixels in the third direction DR3 to detect external input.

The transmission area TA of the cover window CW may at least partially overlap with the display area DA and component area EA of the display panel DP. In an embodiment, the transmission area TA may overlap with an entirety of the surface of the display area DA and component area EA, or may overlap with at least a portion of the display area DA and component area EA, for example. Accordingly, users may view images through the transmission area TA or provide external input based on the images. However, the disclosure is not limited thereto. In an embodiment, the area where images are displayed and the area where external input is detected may be separated, for example.

The non-display area PA of the display panel DP may at least partially overlap with the blocking area BBA of the cover window CW. The non-display area PA may be the area covered by the blocking area BBA. The non-display area PA may include a first non-display area PA1 disposed on the outside of the display area DA and a second non-display area PA2 including the driving portion 50, connection wiring, and a bending area. In the embodiment of FIG. 3, the first non-display area PA1 is disposed on three sides of the display area DA, and the second non-display area PA2 is disposed on the remaining one side of the display area DA.

In an embodiment, part of the non-display area PA of the display panel DP may be bent. At this time, part of the non-display area PA may face toward the rear of the display device 1000, allowing the blocking area BBA visible on the front of the display device 1000 to be reduced, and in FIG. 3, the second non-display area PA2 may be bent and disposed on the rear of the display area DA during assembly.

The first component area EA1 may include a transmission part through which light and/or sound may pass and a display layer including multiple pixels. The transmission part is disposed between neighboring (adjacent) pixels and consists of layers through which light and/or sound may pass. The transmission part may be disposed between neighboring (adjacent) pixels, and depending on the embodiment, light-blocking members or layers that do not transmit light may overlap with the first component area EA1. The number of pixels per unit area (hereinafter referred to as resolution) of pixels included in the display area DA (hereinafter referred to as normal pixels) and the number of pixels per unit area of pixels included in the first component area EA1 (hereinafter referred to as first component pixels) may be the same.

The second component area EA2 may include a light transmission area composed of transparent layers for light to pass through, and in the light transmission area, no conductive or semiconductor layers are disposed, and it may have a structure that does not block light by including openings overlapping with the position corresponding to the second component area EA2 in layers including or consisting of light-blocking materials, such as pixel defining layers and/or light-blocking members. The number of pixels per unit area of pixels included in the second component area EA2 (hereinafter referred to as second component pixels) may be smaller than the number of pixels per unit area of normal pixels included in the display area DA. As a result, the resolution of the second component pixels may be lower than the resolution of normal pixels.

The driving portion 50 may be disposed (e.g., mounted) on the second non-display area PA2 and may be disposed (e.g., mounted) on the bending area or disposed on one side of opposite sides of the bending area. The driving portion 50 may be provided in chip form.

The driving portion 50 may be electrically connected to the display area DA and component area EA to deliver electrical signals to pixels in the display area DA and component area EA. In an embodiment, the driving portion 50 may provide data signals to pixels PX arranged in the display area DA, for example. In an embodiment, the driving portion 50 may include a touch driving circuit and may be electrically connected to touch sensors arranged in the display area DA and/or component area EA. In addition, the driving portion 50 may be designed to include various circuits other than the above-mentioned circuits or to provide various electrical signals to the display area DA.

A pad portion may be disposed at the end of the second non-display area PA2 of the display device 1000, and the pad portion may be electrically connected to a flexible printed circuit board (“FPCB”) including driving chips. Here, the driving chips disposed on the flexible printed circuit board may include various driving circuits and connectors for power supply to drive the display device 1000. Depending on the embodiment, a rigid printed circuit board (“PCB”) may be used instead of the flexible printed circuit board.

The optical element ES may be arranged below the display panel DP. The optical element ES may include a first optical element ES1 overlapping with the first component area EA1 and a second optical element ES2 overlapping with the second component area EA2.

The first optical element ES1 may be an electronic component using light or sound. In an embodiment, the first optical element ES1 may be a sensor using light reception such as an infrared sensor, a sensor that measures distance or recognizes fingerprints by outputting and detecting light or sound, a relatively small lamp that outputs light, or a speaker that outputs sound, for example. For light-using electronic components, various wavelength bands of light including visible light, infrared light, and ultraviolet light may be used.

The second optical element ES2 may be at least one of a camera, an IR camera, a dot projector, an IR illuminator, and a Time-of-Flight (“ToF”) sensor.

The housing HM may be combined with the cover window CW. The cover window CW may be arranged on the front surface of the housing HM. The housing HM may provide a predetermined accommodation space when combined with the cover window CW. The display panel DP and optical element ES may be accommodated in the predetermined accommodation space provided between the housing HM and cover window CW.

The housing HM may include materials having relatively high rigidity. In an embodiment, the housing HM may include glass, plastic, or metal, or may include multiple frames and/or plates composed of combinations thereof, for example. The housing HM may stably protect the components of the display device 1000 accommodated in the internal space from external impact.

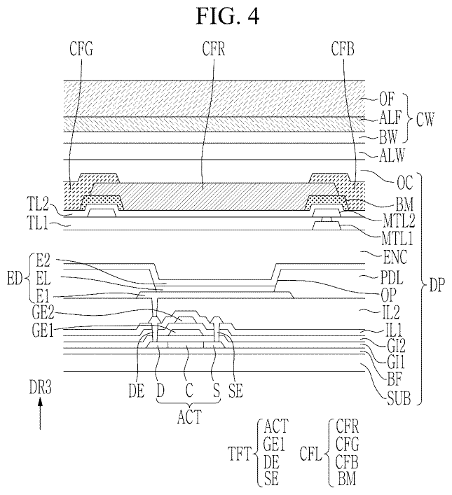

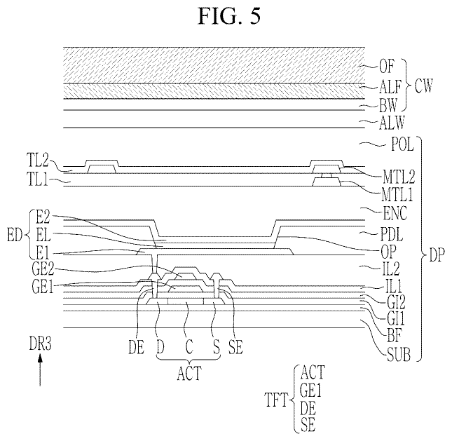

Hereinafter, a display device in an embodiment will be described in more detail with reference to FIGS. 4 and 5. FIGS. 4 and 5 are cross-sectional views of a display area of an embodiment of a display device.

First, referring to FIG. 4, a display device in an embodiment includes a display panel DP and a cover window CW, and the cover window CW may include a base window (also referred to as a window) BW and an optical film OF.

First, the substrate SUB may include materials having rigid characteristics such as glass, or flexible materials that may be bent such as plastic or polyimide.

A buffer layer BUF may be disposed on the substrate SUB. The buffer layer BUF may make the surface of the substrate SUB flat and block the penetration of impurities. The buffer layer BUF may include inorganic insulating materials such as silicon nitride (SiNx), silicon oxide (SiOx), and silicon oxynitride (SiOxNy).

A semiconductor layer ACT may be disposed on the buffer layer BUF. The semiconductor layer ACT may include any one of amorphous silicon, polycrystalline silicon, and oxide semiconductor. In an embodiment, the semiconductor layer ACT may include low-temperature polysilicon (“LTPS”) or include an oxide semiconductor including or consisting of at least one of zinc (Zn), indium (In), gallium (Ga), tin (Sn), and any combinations thereof, for example. In an embodiment, the semiconductor layer ACT may include indium-gallium-zinc oxide (“IGZO”), for example. The semiconductor layer ACT may include a channel region C, a source region S, and a drain region D distinguished by whether impurities are doped. The source region S and drain region D may have conductive characteristics corresponding to conductors.

A first gate insulating film GI1 may be disposed on the semiconductor layer ACT. The first gate insulating film GI1 may cover the semiconductor layer ACT and substrate SUB. The first gate insulating film GI1 may include inorganic insulating materials such as silicon nitride (SiNx), silicon oxide (SiOx), and silicon oxynitride (SiOxNy).

A gate electrode GE1 may be disposed on the first gate insulating film GI1. The gate electrode GE1 may include metals or metal alloys such as copper (Cu), molybdenum (Mo), aluminum (Al), silver (Ag), chromium (Cr), tantalum (Ta), and titanium (Ti). The gate electrode GE1 may consist of a single layer or multiple layers. The region of the semiconductor layer ACT overlapping with the gate electrode GE1 in a plan view may be the channel region C. In this description, “in a plan view” means when viewed in a direction (i.e., third direction DR3) perpendicular to a plane parallel to the first direction DR1 and second direction DR2.

A second gate insulating film GI2 may be disposed on the gate electrode GE1. The second gate insulating film GI2 may include inorganic insulating materials such as silicon nitride (SiNx), silicon oxide (SiOx), and silicon oxynitride (SiOxNy).

A capacitor electrode GE2 may be disposed on the second gate insulating film GI2. The capacitor electrode GE2 may overlap with the gate electrode GE1 to form a capacitor.

A first insulating film IL1 may be disposed on the capacitor electrode GE2. The first insulating film IL1 may include inorganic insulating materials such as silicon nitride (SiNx), silicon oxide (SiOx), and silicon oxynitride (SiOxNy).

A source electrode SE and a drain electrode DE may be disposed on the first insulating film IL1. The source electrode SE and drain electrode DE are electrically connected to the source region S and drain region D of the semiconductor layer ACT, respectively, through openings defined in the first insulating film IL1, second gate insulating film GI2, and first gate insulating film GI1. Accordingly, the aforementioned semiconductor layer ACT, gate electrode GE1, source electrode SE, and drain electrode DE may form one transistor TFT. The source electrode SE and drain electrode DE may include metals or metal alloys such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta).

A second insulating film IL2 may be disposed on the source electrode SE and drain electrode DE. The second insulating film IL2 covers the source electrode SE and drain electrode DE. The second insulating film IL2 may planarize the surface of the substrate SUB with the transistor. The second insulating film IL2 may be an organic insulating film and may include one or more materials selected from the group consisting of polyimide, polyamide, acrylic resin, benzocyclobutene, and phenolic resin.

A first electrode E1 may be disposed on the second insulating film IL2. The first electrode E1 may consist of a single layer including a transparent conductive oxide film or metal material, or multiple layers including these. The transparent conductive oxide film may include Indium Tin Oxide (“ITO”), poly-ITO, Indium Zinc Oxide (“IZO”), IGZO, and Indium Tin Zinc Oxide (“ITZO”). The metal material may include silver (Ag), molybdenum (Mo), copper (Cu), gold (Au), and aluminum (Al). In an embodiment, the first electrode E1 may have a three-layer structure of ITO/Ag/ITO, for example.

The first electrode E1 may be physically and electrically connected to the drain electrode DE through an opening in the second insulating film IL2. Accordingly, the first electrode E1 may receive output current to be delivered to the emission layer EL from the drain electrode DE.

A pixel defining layer PDL may be disposed on the first electrode E1 and second insulating film IL2. The pixel defining layer PDL may define a pixel opening OP exposing an upper surface of the first electrode E1. The pixel opening OP may overlap with the center portion of the first electrode E1 and may be spaced apart from the edges of the first electrode E1. The pixel defining layer PDL may define the position where an emission layer EL will be disposed on the first electrode E1 exposed by the pixel opening OP.

An emission layer EL may be disposed in the pixel opening OP. The emission layer EL may include organic materials that emit red, green, blue, or other colored light. The emission layers EL emitting red, green, and blue light may include low-molecular or high-molecular organic materials. While the emission layer EL is shown as a single layer in FIG. 4, auxiliary layers such as an electron injection layer, electron transport layer, hole transport layer, and hole injection layer may also be included, with the hole injection layer and hole transport layer disposed below the emission layer EL, and the electron transport layer and electron injection layer disposed above the emission layer EL.

According to the embodiment, the emission layer EL may include quantum dots. The quantum dots (also referred to as semiconductor nanocrystals) may include II-VI compounds, III-V compounds, IV-VI compounds, group IV elements or compounds, I-III-VI compounds, II-III-VI compounds, I-II-IV-VI compounds, or combinations thereof. The quantum dots may not include cadmium.

A second electrode E2 may be disposed on the emission layer EL. The second electrode E2 may include or consist of a transparent conductive layer including ITO, IZO, IGZO, and ITZO. Also, the second electrode E2 may have semi-transparent characteristics, and in this case, it may form a micro-cavity together with the first electrode E1. By the micro-cavity structure, due to the spacing and characteristics between the electrodes, predetermined wavelength light may be emitted upward, resulting in displaying red, green, or blue. The second electrode E2 may deliver a common voltage to multiple pixels.

The first electrode E1, emission layer EL, and second electrode E2 may form one light-emitting element ED which may be a light-emitting diode. One of the first electrode E1 and second electrode E2 may form an anode electrode of the light-emitting element ED and a remaining (the other) one may form a cathode electrode. In this embodiment, it was mainly explained with the first electrode E1 being the anode electrode of the light-emitting element ED and the second electrode E2 being the cathode electrode.

An encapsulation layer ENC may be disposed on the second electrode E2. The encapsulation layer ENC may include at least one inorganic film and at least one organic film.

Sensing insulating layers TL1 and TL2 and multiple sensing electrodes MTL1 and MTL2 are disposed on the encapsulation layer ENC for touch sensing. In the embodiment of FIG. 4, touch is sensed in a capacitive type using two sensing electrodes MTL1 and MTL2, but in embodiments, touch may also be sensed in a self-cap method using only one sensing electrode. Here, the sensing electrodes MTL1 and MTL2 may include metals or metal alloys such as aluminum (Al), copper (Cu), silver (Ag), gold (Au), molybdenum (Mo), titanium (Ti), and tantalum (Ta), and may consist of a single layer or multiple layers.

A color filter layer CFL may be disposed on the second sensing insulating layer TL2. The color filter layer CFL may include color filters CFR, CFG, and CFB and a light-blocking layer BM.

The color filters include a red color filter CFR that transmits red light, a green color filter CFG that transmits green light, and a blue color filter CFB that transmits blue light. Each color filter CFR, CFG, and CFB may be disposed to overlap with the first electrode E1 in a plan view. Light emitted from the emission layer EL may all have the same color and be changed to the respective colors when passing through the color filters CFR, CFG, and CFB. Not limited to this, the emission layer EL may emit different colored lights and pass through color filters of the same color to enhance the displayed color expression.

Depending on the embodiment, the color filters CFR, CFG, and CFB may be replaced with or additionally include color conversion layers. The color conversion layers may include quantum dots.

A light-blocking layer BM may be disposed between neighboring (adjacent) color filters CFR, CFG, and CFB. The light-blocking layer BM may include or consist of organic materials having a black color. The organic materials having a black color may include light-blocking materials. In an embodiment, the light-blocking layer BM may be omitted.

An overcoat layer OC covering the color filters CFR, CFG, and CFB and light-blocking layer BM is disposed on the color filters CFR, CFG, and CFB and light-blocking layer BM. The overcoat layer OC is for planarizing the upper surface of the display panel and may be a transparent organic insulating film including one or more materials selected from the group consisting of polyimide, polyamide, acrylic resin, benzocyclobutene, and phenolic resin.

A window adhesive layer ALW and base window BW may be disposed on the display panel DP. The window adhesive layer ALW is disposed between the display panel DP and base window BW, and the display panel DP and base window BW may be bonded by the window adhesive layer ALW. The window adhesive layer ALW may include or consist of optically transparent adhesive or pressure-sensitive adhesive. The window adhesive layer ALW may include adhesive materials such as acrylics polymers, ethylene vinyl acetate polymers, nitriles polymers, silicone rubbers, butyl rubber, styrene block copolymers, vinyl ethers polymers, urethane polymers, and epoxy polymers.

A film adhesive layer (also referred to as an adhesive layer) ALF and an optical film OF may be disposed on the base window BW. The film adhesive layer ALF is disposed between the base window BW and the optical film OF, and the base window BW and the optical film OF may be bonded by the film adhesive layer ALF.

At least one of the film adhesive layer ALF and optical film OF may include an ultraviolet absorbent. The ultraviolet absorbent may absorb ultraviolet light entering the display panel. Accordingly, this may prevent the phenomenon of reflected light from the display panel having a bluish color.

A content of the ultraviolet absorbent may be 1 wt % to 90 wt %. In the description, ‘the content of the ultraviolet absorbent’ may refer to a weight percent of the ultraviolet absorbent relative to a total mass of a layer (e.g., the film adhesive layer ALF or the optical film OF, or both) in which the ultraviolet absorbent is included. The ultraviolet absorbent may be included in a relatively low concentration of about 1 wt % to about 10 wt %, about 1 wt % to about 5 wt %, or about 1 wt % to about 3 wt %. Even when included in a relatively low concentration, the reflection color characteristics of the display device may be improved. Not limited to this, the content of the ultraviolet absorbent may also be included in a relatively high concentration of about 10 wt % or more.

The ultraviolet absorbent may include at least one of compounds represented by Chemical Formulas 1 to 2 below.

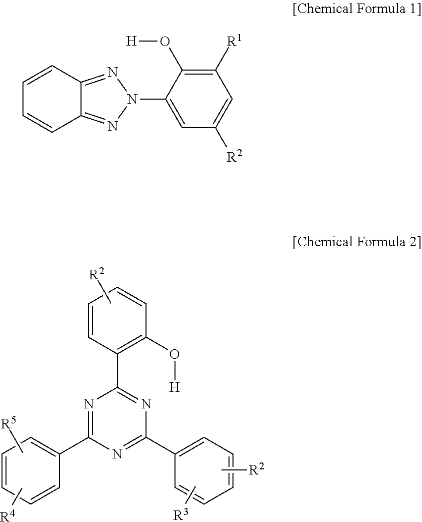

R1 to R5 are each independently a substituent or a hydrogen atom, and the substituents are each independently selected from alkyl group, cycloalkyl group, aryl group, acylamino group, alkylthio group, arylthio group, alkenyl group, halogen atom, alkynyl group, heterocyclic group, alkylsulfonyl group, arylsulfonyl group, alkylsulfinyl group, arylsulfinyl group, phosphono group, acyl group, carbamoyl group, sulfamoyl group, sulfonamide group, cyano group, alkoxy group, aryloxy group, heterocyclic oxy group, siloxy group, acyloxy group, sulfonic acid group, salt of sulfonic acid, aminocarbonyloxy group, amino group, anilino group, imide group, ureido group, alkoxycarbonylamino group, alkoxycarbonyl group, aryloxycarbonyl group, heterocyclic thio group, thioureido group, carboxyl group, salt of carboxylic acid, hydroxyl group, mercapto group, or nitro group.

Also, the ultraviolet absorbent may further include a compound represented by Chemical Formula 3 below. The compound represented by Chemical Formula 3 below may function as a reaction stabilizer.

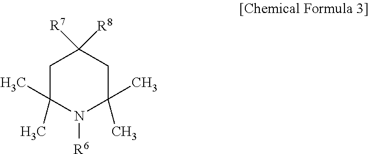

R6 to R8 are substituents or hydrogen atoms, and the substituents are each independently selected from alkyl group, cycloalkyl group, aryl group, acylamino group, alkylthio group, arylthio group, alkenyl group, halogen atom, alkynyl group, heterocyclic group, alkylsulfonyl group, arylsulfonyl group, alkylsulfinyl group, arylsulfinyl group, phosphono group, acyl group, carbamoyl group, sulfamoyl group, sulfonamide group, cyano group, alkoxy group, aryloxy group, heterocyclic oxy group, siloxy group, acyloxy group, sulfonic acid group, salt of sulfonic acid, aminocarbonyloxy group, amino group, anilino group, imide group, ureido group, alkoxycarbonylamino group, alkoxycarbonyl group, aryloxycarbonyl group, heterocyclic thio group, thioureido group, carboxyl group, salt of carboxylic acid, hydroxyl group, mercapto group, or nitro group.

In an embodiment, the ultraviolet absorbent may use compounds such as benzotriazole compounds like 2-(2′-hydroxy-5′-methylphenyl)benzotriazole, 2-(3′,5′-di-tert-butyl-2′-hydroxyphenyl)benzotriazole, 2-(5′-tert-butyl-2′-hydroxyphenyl)benzotriazole, 2-(2-hydroxy-5-(1,1,3,3-tetramethylbutyl)phenyl)benzotriazole, 2-(3′,5′-di-tert-butyl-2′-hydroxyphenyl)-5-benzotriazole, 2-(3′-tert-butyl-2′-hydroxyphenyl-5′-methylphenyl)-5-benzotriazole, 2-(3′-sec-butyl-5′-tert-butyl-2′-hydroxyphenyl)benzotriazole, 2-(2′-hydroxy-4′-octyloxyphenylphenyl)-5-benzotriazole, or 2-(3′,5′-di-tert-butyl-2′-hydroxyphenyl)benzotriazole, benzophenone compounds like hydroxybenzophenone series compounds having 4-hydroxy, 4-methoxy, 4-octyloxy, 4-decyloxy, 4-dodecyloxy, 4-benzyloxy, 4,2′,4′-trihydroxy, or 2′-hydroxy-4,4′-dimethoxy functional groups, benzoic acid ester compounds like compounds having substituted benzoic acid ester structures such as 4-tert-butyl-phenyl salicylate, phenyl salicylate, octylphenyl salicylate, dibenzoyl resorcinol, bis(4-tert-butyl-benzoyl) resorcinol, benzoyl resorcinol, 2,4-di-tert-butylphenyl-3,5′-di-tert-butyl-4-hydroxybenzoate, hexadecyl3,5-di-tert-butyl-4-4hydroxybenzoate, octadecyl 3,5-di-tert-butyl-4-hydroxybenzoate, or 2-methyl-4,6-di-tert-butylphenyl 3,5-di-tert-butyl-4-hydroxybenzoate, or triazine compounds, for example.

Referring to FIG. 5, a polarization layer POL may be disposed on the second sensing insulating layer TL2 instead of the color filter layer CFL. The polarization layer POL may prevent display quality degradation that occurs when users view external light being reflected from the first electrode E1 or sidewalls of pixel openings OP of the pixel defining layer PDL.

The remaining components except for the polarization layer POL may be the same as in the embodiment of FIG. 4, and will be omitted from description below.

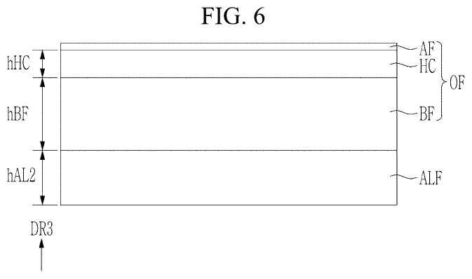

Hereinafter, referring to FIG. 6, the film adhesive layer ALF and optical film OF disposed above the base window BW of FIGS. 4 and 5 will be examined in more detail. FIG. 6 is a cross-sectional view of an embodiment of a portion of a display device.

Referring to FIG. 6, an optical film OF is disposed above the film adhesive layer ALF. The optical film OF may include a base layer BF and a coating layer HC. The optical film OF may be disposed above the display panel to protect the display panel from external impact. A hardness of the optical film OF may be about 30 Vickers hardness (Hv) or more, and a crack strain may be about 2% or more.

The film adhesive layer ALF may include or consist of optically transparent adhesive or pressure-sensitive adhesive. The film adhesive layer ALF may include adhesive materials such as acrylics polymers, ethylene vinyl acetate polymers, nitriles polymers, silicone rubbers, butyl rubber, styrene block copolymers, vinyl ethers polymers, urethane polymers, and epoxy polymers. The film adhesive layer ALF may consist of a single layer or multiple layers.

The thickness hALF of the film adhesive layer ALF in the third direction DR3 may be about 20 micrometers (μm) to about 50 μm, e.g., about 30 μm to about 40 μm, and may be about 35 μm. However, the thickness hALF of the film adhesive layer ALF is not limited to this and may be changed within a range that maintains adhesion strength and durability.

A base layer BF may be disposed above the film adhesive layer ALF. The base layer BF may include transparent materials. The base layer BF may include glass or polymer films. In an embodiment, it may include polymer films such as polyimide (“PI”), polyethylene terephthalate (“PET”), triacetyl cellulose (“TAC”), and cyclic olefin polymer (“COP”), for example. The base layer BF may consist of a single layer or multiple layers.

The thickness hBF of the base layer BF in the third direction DR3 may be about 50 μm to about 100 μm, e.g., about 65 μm. The thickness hBF of the base layer BF is not limited to this and may be changed within a range that maintains mechanical strength and flexibility.

A coating layer HC may be disposed above the base layer BF. The coating layer HC may protect the display device from external impact. The coating layer HC may include transparent materials and may include materials such as Acrylate, Urethane Acrylate, and Polyurethane. The coating layer HC may consist of a single layer or multiple layers.

The thickness hHC of the coating layer HC in the third direction DR3 may be about 3 μm to about 20 μm, e.g., about 5 μm to about 10 μm. The thickness hHC of the coating layer HC is not limited to this and may be changed within a range that maintains hardness and flexibility.

At least one of the film adhesive layer ALF, base layer BF, and coating layer HC may include an ultraviolet absorbent. The ultraviolet absorbent may absorb ultraviolet light entering the display panel. Accordingly, the phenomenon in which the color of light reflected from the display panel is bluish may be improved, thereby providing a uniform color.

In an embodiment, the coating layer HC may include the ultraviolet absorbent, while the film adhesive layer ALF and base layer BF may not include the ultraviolet absorbent, for example. Also, the base layer BF may include the ultraviolet absorbent, while the film adhesive layer ALF and coating layer HC may not include the ultraviolet absorbent. Similarly, the film adhesive layer ALF may include the ultraviolet absorbent, while the coating layer HC and base layer BF may not include the ultraviolet absorbent.

At least two of the film adhesive layer ALF, base layer BF, and coating layer HC may include the ultraviolet absorbent. In an embodiment, the coating layer HC and base layer BF may each include the ultraviolet absorbent while the film adhesive layer ALF may not include the ultraviolet absorbent, for example. The coating layer HC and film adhesive layer ALF may include the ultraviolet absorbent while the base layer BF may not include the ultraviolet absorbent. The base layer BF and film adhesive layer ALF may include the ultraviolet absorbent while the coating layer HC may not include the ultraviolet absorbent. Similarly, the film adhesive layer ALF, base layer BF, and coating layer HC may each include the ultraviolet absorbent.

When at least two of the film adhesive layer ALF, base layer BF, and coating layer HC include or consist of the ultraviolet absorbent, the concentration of ultraviolet absorbent contained in each layer may be reduced. Accordingly, maintaining transparency of each layer may be easier.

When at least two of the film adhesive layer ALF, base layer BF, and coating layer HC include or consist of the ultraviolet absorbent, the amount of ultraviolet absorbent contained in each layer may be made different from each other. By making the transmittance according to wavelength different for each layer, reliability degradation possibility may be minimized and stability may be increased. In an embodiment, the amount of ultraviolet absorbent in one layer may be made relatively small to design transmittance of external light at 380 nanometers (nm) to be 20% or less and transmittance at 405 nm to be 70%, and the amount of ultraviolet absorbent in another layer may be made relatively large to design transmittance at 405 nm to be 20% or less and transmittance at 430 nm to be 70% or more, for example. This is just one example, and the transmittance for the wavelength of each layer may be freely changed by adjusting the amount of ultraviolet absorbent.

Also, the amount of ultraviolet absorbent contained in each layer may be made different according to the thicknesses of the film adhesive layer ALF, base layer BF, and coating layer HC. The content of ultraviolet absorbent may be made smaller in layers with smaller thickness and larger in layers with greater thickness. In an embodiment, the thickness hHC of the coating layer HC may be smaller than the thickness hBF of the base layer BF, and when both the coating layer HC and base layer BF include ultraviolet absorbent, the amount of ultraviolet absorbent contained in the coating layer HC may be smaller than the amount contained in the base layer BF, for example. Also, the thickness hHC of the coating layer HC may be smaller than the thickness hALF of the film adhesive layer ALF, and when both the coating layer HC and film adhesive layer ALF include ultraviolet absorbent, the amount of ultraviolet absorbent contained in the coating layer HC may be smaller than the amount contained in the base layer BF.

The content of the ultraviolet absorbent may be 1 wt % to 90 wt %. The ultraviolet absorbent may be included in a relatively low concentration of about 1 wt % to about 10 wt %, about 1 wt % to about 5 wt %, or about 1 wt % to about 3 wt %. Not limited to this, the content of the ultraviolet absorbent may also be included in a relatively high concentration of about 10 wt % or more.

The optical film OF may further include an anti-reflection layer AF disposed above the coating layer HC. The anti-reflection layer AF may be, e.g., a film having a reflectance of about 1% or less. The anti-reflection layer AF may be disposed at the outermost of the display device to reduce external light reflectance.

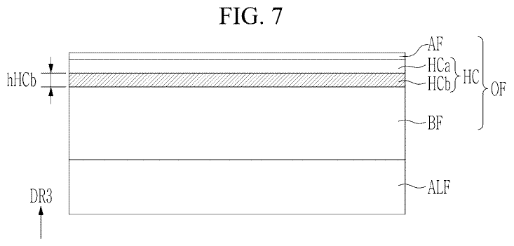

Hereinafter, referring to FIGS. 7 to 12, the film adhesive layer ALF and optical film OF disposed above the base window BW of FIGS. 4 and 5 will be examined. The explanation for components identical to FIG. 6 will be omitted. FIGS. 7 to 12 are cross-sectional views of an embodiment of portions of a display device.

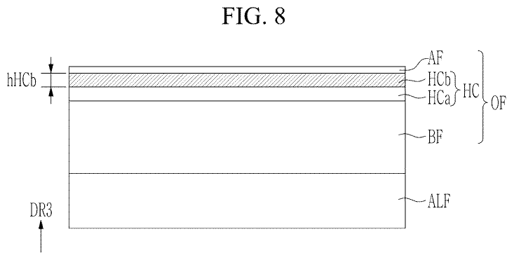

Referring to FIGS. 7 and 8, the coating layer HC may consist of multiple layers. In an embodiment, the coating layer HC may include a first coating layer HCa and a second coating layer HCb, and the second coating layer HCb may include the ultraviolet absorbent while the first coating layer HCa may not include the ultraviolet absorbent, for example. That is, the coating layer HC may consist of multiple layers including a functional layer including or consisting of the ultraviolet absorbent.

As shown in FIG. 7, the first coating layer HCa may be disposed above the second coating layer HCb. In this case, the first coating layer HCa covers the second coating layer HCb including or consisting of the ultraviolet absorbent, allowing the ultraviolet absorbent to be stably contained.

Not limited to this, as shown in FIG. 8, the second coating layer HCb may be disposed above the first coating layer HCa. The thickness hHCb of the second coating layer HCb may be 10 μm or less.

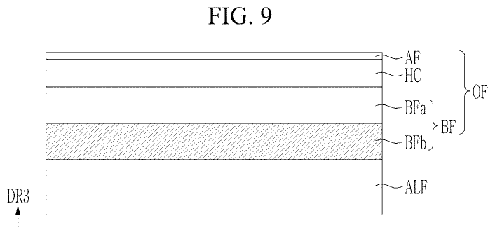

Referring to FIG. 9, the base layer BF may consist of multiple layers. In an embodiment, the base layer BF may include a first base layer BFa and a second base layer BFb, and the second base layer BFb may include the ultraviolet absorbent while the first base layer BFa may not include the ultraviolet absorbent, for example. As shown in FIG. 9, the first base layer BFa may be disposed above the second base layer BFb, or conversely, the second base layer BFb may be disposed above the first base layer BFa.

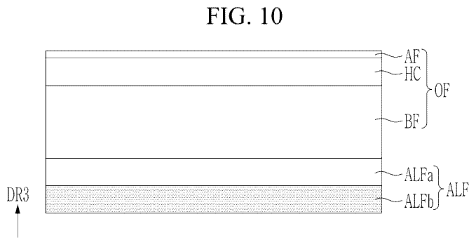

Referring to FIG. 10, the film adhesive layer ALF may consist of multiple layers. In an embodiment, the film adhesive layer ALF may include a first adhesive layer ALFa and a second adhesive layer ALFb, and the second adhesive layer ALFb may include the ultraviolet absorbent while the first adhesive layer ALFa may not include the ultraviolet absorbent, for example. As shown in FIG. 10, the first adhesive layer ALFa may be disposed above the second adhesive layer ALFb, or conversely, the second adhesive layer ALFb may be disposed above the first adhesive layer ALFa.

While not shown in FIGS. 7 to 10, two or more of the coating layer HC, base layer BF, and film adhesive layer ALF may consist of multiple layers, or the coating layer HC, base layer BF, and film adhesive layer ALF may each consist of multiple layers.

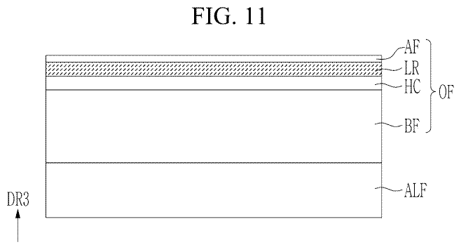

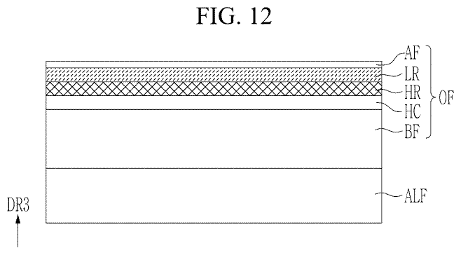

Hereinafter, referring to FIGS. 11 and 12, the film adhesive layer ALF and optical film OF disposed above the base window BW in FIGS. 4 and 5 will be examined. The explanation for components identical to FIG. 6 will be omitted.

Referring to FIG. 11, the optical film OF may further include a low refractive layer LR. The low refractive layer LR may be disposed above the coating layer HC and may be disposed below the anti-reflection layer AF. The low refractive layer LR may improve external light reflection issues. Specifically, it may reduce reflectance through destructive interference between light reflected from the upper surface of the low refractive layer LR and light reflected from the lower surface of the low refractive layer LR. The refractive index of the low refractive layer LR may be about 1.48 or less, and the thickness of the low refractive layer LR may be about 10 nm to about 200 nm.

The low refractive layer LR may include hollow silica. Hollow silica is a structure with air included inside silica, which may lower the refractive index of the low refractive layer LR. The refractive index of the low refractive layer LR may be adjusted by controlling the size and concentration of the hollow silica.

Referring to FIG. 12, the optical film OF may further include a low refractive layer LR and a high refractive layer HR. The low refractive layer LR and high refractive layer HR may be disposed above the coating layer HC and below the anti-reflection layer AF. The high refractive layer HR may be disposed below the low refractive layer LR.

By placing the high refractive layer HR below the low refractive layer LR, destructive interference between light reflected from the upper surface of the low refractive layer LR and light reflected from the interface between the low refractive layer LR and high refractive layer HR may occur more easily. At this time, the refractive index of the low refractive layer LR may be about 1.48 or less, and the refractive index of the high refractive layer HR may be about 1.55 or more.

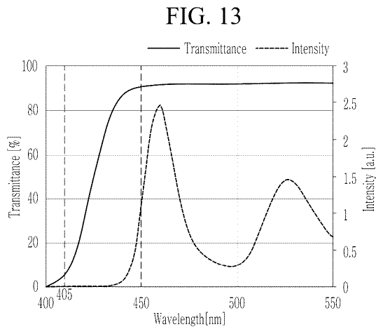

Hereinafter, referring to FIG. 13, the transmittance of external light according to wavelength will be examined. FIG. 13 is a graph showing transmittance of an embodiment of light according to wavelength of a display device and intensity of light according to wavelength of a light-emitting layer emitting blue light.

Referring to FIG. 13, the display device in an embodiment includes an ultraviolet absorbent and may transmit about 10% or less of light having a wavelength of 405 nm or less. Also, it may transmit about 85% or more of light having a wavelength of 450 nm or more. That is, short wavelengths are absorbed without penetrating the display panel, so the phenomenon of reflected light having a bluish color may be improved.

Also, the ultraviolet absorbent does not absorb light emitted from the emission layer, so it does not affect the light efficiency of the display device. Referring to FIG. 13, since the emission layer emitting blue light hardly emits light of 450 nm or less, the display device in an embodiment does not reduce the light efficiency of the light-emitting element, and efficiency reduction may occur at 1% or less.

Hereinafter, referring to [Table 1], the color characteristics of the display device in an embodiment will be examined specifically. The display device in an embodiment used an optical film including 3 wt % of ultraviolet absorbent, and the display device according to a comparative example used an optical film not including ultraviolet absorbent.

The reflectance and color distribution of the comparative example and embodiment are as follows.

TABLE 1

| | | Comparative Example | Embodiment |
|---|---|---|---|
| SCI | Reflectance [%] | 3.8 | 3.8 |
| | b* | −2.5 | −1.6 |
| SCE | Reflectance [%] | 0.8 | 0.8 |
| | b* | −4.9 | −3.0 |

In Table 1, b* value represents the axis indicating yellow and blue components of color in CIELAB color space, where the positive (+) direction indicates stronger yellow components and the negative (−) direction indicates stronger blue components. Specular Component Included (“SCI”) mode of the colorimeter measures color or reflectance including specular reflection, while Specular Component Excluded (“SCE”) mode of the colorimeter measures the color or reflectance of the surface itself by blocking specular reflection.

Referring to Table 1, in SCI mode, the b* value of the comparative example is −2.5 and the b* value of the embodiment is −1.6, with the b* value of the embodiment being closer to 0. That is, the display device in the embodiment shows reduced bluish tint. The reflectance was maintained at 3.8% for both the comparative example and the embodiment.

Similarly, in SCE mode, the b* value of the comparative example is −4.9 and the b* value of the embodiment is −3.0, with the b* value of the embodiment being closer to 0, showing that the display device in the embodiment exhibits a reduced bluish tint. The reflectance was maintained at 0.8% for both the comparative example and the embodiment.

The display device in embodiments may be applied to various electronic devices. An electronic device in an embodiment includes the above-described display device and may further include modules or devices having other additional functions besides the display device.

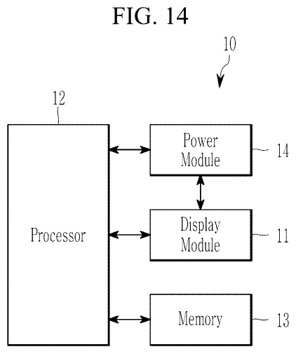

FIG. 14 is a block diagram of an embodiment of an electronic device. Referring to FIG. 14, an electronic device 10 in an embodiment may include a display module 11, a processor 12, a memory 13, and a power module 14.

The processor 12 may include at least one of a central processing unit (“CPU”), application processor (“AP”), graphic processing unit (“GPU”), communication processor (“CP”), image signal processor (“ISP”), and controller.

Memory 13 may store data information desired for the operation of processor 12 or display module 11. When processor 12 executes applications stored in memory 13, image data signals and/or input control signals are delivered to display module 11, and display module 11 may process the received signals to output image information through the display screen.

The power module 14 may include a power supply module such as a power adapter or battery device, and a power conversion module that converts and generates power desired for the operation of electronic device 10 from the power supplied by the power supply module.

At least one of the components of the electronic device 10 described above may be included within the display device in the embodiments described above. Also, some of the individual modules functionally included in one module may be included in the display device while other parts may be provided separately from the display device. In an embodiment, the display device may include the display module 11, while processor 12, memory 13, and power module 14 may be provided in the form of other devices within electronic device 10 rather than in the display device, for example.

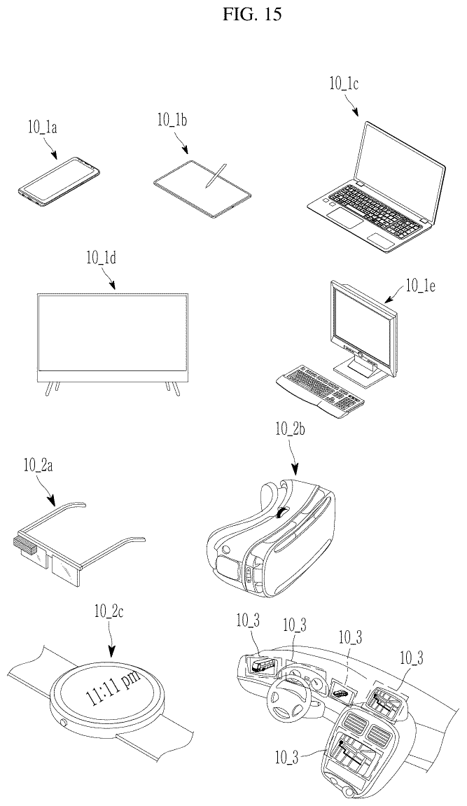

FIG. 15 are schematic diagrams of an embodiment of electronic devices.

Referring to FIG. 15, various electronic devices to which display devices in embodiments are applied may include not only image display electronic devices such as smartphones 10_1a, tablet PCs 10_1b, laptops 10_1c, televisions (“TVs”) 10_1d, and desktop monitors 10_1e, but also wearable electronic devices including display modules such as smart glasses 10_2a, head mounted displays 10_2b, and smart watches 10_2c, and vehicle electronic devices including display modules such as vehicle instrument panels, CIDs arranged in center fascia, dashboards, and room mirror displays 10_3.

While the disclosure has been described with reference to embodiments, it should be understood that various changes and modifications may be made within the scope of the basic concepts of the disclosure as defined by the claims and their equivalents.

What is claimed is:

1. A display device comprising:
a display panel;
a window disposed on a front surface of the display panel;
an optical film disposed on the window, the optical film including:
a base layer disposed on the window; and
a coating layer disposed on the base layer; and
an adhesive layer disposed between the window and the optical film,
wherein at least one of the base layer, the coating layer, and the adhesive layer includes an ultraviolet absorbent, and
wherein a content of the ultraviolet absorbent is about 1 wt % to about 10 wt %.

2. The display device of claim 1, wherein the content of the ultraviolet absorbent is about 1 wt % to about 5 wt %.

3. The display device of claim 1, wherein the content of the ultraviolet absorbent is about 1 wt % to about 3 wt %.

4. The display device of claim 1, wherein:
the coating layer includes a first coating layer and a second coating layer, and
the second coating layer includes the ultraviolet absorbent.

5. The display device of claim 4, wherein a thickness of the second coating layer is about 10 micrometers or less.

6. The display device of claim 4, wherein the second coating layer is disposed between the first coating layer and the base layer.

7. The display device of claim 4, wherein the first coating layer is disposed between the second coating layer and the base layer.

8. The display device of claim 1, wherein:
the base layer includes a first base layer and a second base layer, and
the second base layer includes the ultraviolet absorbent.

9. The display device of claim 1, wherein:
the adhesive layer includes a first adhesive layer and a second adhesive layer, and
the second adhesive layer includes the ultraviolet absorbent.

10. The display device of claim 1, wherein:
each of the base layer and the coating layer includes the ultraviolet absorbent,
a thickness of the base layer is greater than a thickness of the coating layer, and
a content of the ultraviolet absorbent in the base layer is greater than a content of the ultraviolet absorbent in the coating layer.

11. The display device of claim 1, wherein:
each of the adhesive layer and the coating layer includes the ultraviolet absorbent,
a thickness of the adhesive layer is greater than a thickness of the coating layer, and
a content of the ultraviolet absorbent in the adhesive layer is greater than a content of the ultraviolet absorbent in the coating layer.

12. The display device of claim 1, wherein the optical film further includes a low refractive layer disposed on the coating layer and having a refractive index.

13. The display device of claim 12, wherein a refractive index of the low refractive layer is about 1.48 or less.

14. The display device of claim 12, wherein the optical film further includes a high refractive layer disposed between the coating layer and the low refractive layer and having a refractive index higher than the refractive index of the low refractive layer.

15. The display device of claim 14, wherein a refractive index of the high refractive layer is about 1.55 or more.

16. The display device of claim 1, wherein the optical film further includes an anti-reflection layer disposed at an outermost.

17. The display device of claim 1, wherein a hardness of the optical film is about 30 Vickers hardness or more.

18. The display device of claim 1, wherein a crack strain of the optical film is about 2% or more.

19. The display device of claim 1, which transmits about 10% or less of light having a wavelength of 405 nanometers or less, and about 85% or more of light having a wavelength of 450 nanometers or more.

20. An electronic device comprising:
a display device including:
a display panel;
a window disposed on a front surface of the display panel;
an optical film disposed on the window, the optical film including:
a base layer disposed on the window, and
a coating layer disposed on the base layer;
an adhesive layer disposed between the window and the optical film;
a processor;
a memory; and
a power module,
wherein at least one of the base layer, the coating layer, and the adhesive layer includes an ultraviolet absorbent, and
wherein a content of the ultraviolet absorbent is about 1 wt % to about 10 wt %.
